(19) United States
(12) Patent Application Publication
(10) Pub. No.: US 2026/0068492 A1
(43) Pub. Date: Mar. 5, 2026

(54) DISPLAY DEVICE AND ELECTRONIC DEVICE

(71) Applicant: Samsung Display Co., LTD., Yongin-si (KR)

(72) Inventors: Ho Ryun CHUNG, Yongin-si (KR); Myung Hwan KIM, Yongin-si (KR); Eunjae NA, Yongin-si (KR); MUNHWA SONG, Yongin-si (KR); Young Hoon LEE, Yongin-si (KR)

(21) Appl. No.: 19/221,893

(22) Filed: May 29, 2025

(30) Foreign Application Priority Data
Aug. 28, 2024 (KR) 10-2024-0115855

(51) Int. Cl. H10K 59/80; H10K 59/95

(52) U.S. Cl. CPC H10K 59/873; H10K 59/95

(57) ABSTRACT

A display device includes a display panel including a front side and a back side, a pad portion on a first surface of the back side, a printed circuit board connected to the pad portion, an anisotropic conductive film between the back side and the printed circuit board, an adhesive layer on a second surface opposite the first surface, and a lower film on the adhesive layer. The printed circuit board includes a bonding portion bonded to the pad portion through the anisotropic conductive film, the adhesive layer having a first interface between the adhesive layer and the back side and a second interface between the adhesive layer and the lower film. An adhesive strength of a first portion of the first interface overlapping the bonding portion is from 100 gf/inch to 300 gf/inch, and smaller than an adhesive strength of the second interface to the lower film.

This application claims priority to Korean Patent Application No. 10-2024-0115855, filed on Aug. 28, 2024, and all the benefits accruing therefrom under 35 U.S.C. § 119, the content of which in its entirety is herein incorporated by reference.

### BACKGROUND

### 1. Field

The present disclosure relates to a display device and an electronic device.

### 2. Description of the Related Art

Display devices such as organic light emitting diode displays and liquid crystal displays include display panels manufactured by forming multiple layers and elements on a substrate. Recently, flexible display panels and display devices including the same are being developed.

Display devices may be classified into bendable display devices, foldable display devices, rollable display devices, and stretchable display devices depending on their purpose or form. Among these, the foldable display device may be folded and unfolded like a book.

A display device using a substrate having flexible properties may be designed to bend—for example, the edge of a display panel having a pad portion—thereby reducing dead space compared to a display device using a substrate having rigid properties.

Reducing dead space allows the reduction of the bezel width of the display device.

### SUMMARY

Embodiments aim to prevent delamination between thin films of a display panel due to expansion of a lower film when a display device is driven.

According to an embodiment, a display device includes a bent display panel including a front side and a back side, which face each other, a pad portion disposed on a first surface of the back side, a printed circuit board electrically connected to the pad portion, an anisotropic conductive film disposed between the back side and the printed circuit board, an adhesive layer disposed on a second surface opposite the first surface of the back side of the display panel, and a lower film disposed on the adhesive layer, where the printed circuit board includes a bonding portion bonded to the pad portion through the anisotropic conductive film, the adhesive layer having a first interface disposed between the adhesive layer and the back side and a second interface disposed between the adhesive layer and the lower film, an adhesive strength of a first portion of the first interface overlapping the bonding portion in a plan view to the back side is from 100 gram-force per inch (gf/inch) to 300 gf/inch, and the adhesive strength of the first portion to the back side is smaller than an adhesive strength of the second interface to the lower film.

The display panel may further include a cover panel disposed on the lower film and disposed below the front side of the display panel, and a third interface which is an interface between the cover panel and the lower film, a fourth interface which is an interface between the back side and the anisotropic conductive film, and a fifth interface which is an interface between the anisotropic conductive film and the bonding portion, where an adhesive strength of the fifth interface to the bonding portion may be greater than an adhesive strength of the fourth interface to the anisotropic conductive film, and the adhesive strength of the fourth interface to the anisotropic conductive film may be greater than an adhesive strength of the third interface to the lower film.

The adhesive strength of the third interface to the lower film may be greater than the adhesive strength of the second interface to the lower film.

The adhesive strength of the third interface to the lower film may be from 700 gf/inch to 1200 gf/inch.

The adhesive strength of the second interface to the adhesive layer may be 500 gf/inch to 700 gf/inch.

The adhesive strength of the fourth interface to the anisotropic conductive film may be 1,300 gf/inch to 1,500 gf/inch.

The adhesive strength of the fifth interface to the bonding portion may be 1500 gf/inch to 1700 gf/inch.

The adhesive strength of the first portion to the back side may be within 10% difference from an adhesive strength of a second portion of the first interface to the back side, which does not overlap the bonding portion in the plan view.

The adhesive strength of the first portion to the back side may be different from the adhesive strength of the second portion.

The adhesive strength of the first portion to the back side may be smaller than the adhesive strength of the second portion to the back side.

The display device may further include a moisture barrier layer disposed between the cover panel and the printed circuit board and disposed on a side of the back side, and a functional layer disposed between the side of the back side of the display panel and the moisture barrier layer.

The display device further includes a coating layer surrounding the anisotropic conductive film, and the coating layer may include a hydrophobic ligand.

The printed circuit board may further include a body portion on which components are arranged, and a cover may be disposed below the body portion, the bonding portion, and the display driving part, where an adhesive strength of the cover to the body portion may be 500 gf/inch to 1200 gf/inch.

A display device according to an embodiment includes a bent display panel including a front side and a back side, which face each other, a pad portion disposed on a first surface of the back side, a printed circuit board electrically connected to the pad portion, an anisotropic conductive film disposed between the back side and the printed circuit board, an adhesive layer disposed on a second surface opposite to the first surface of the back side of the display panel, and a lower film disposed on the adhesive layer, where the printed circuit board includes a bonding portion bonded to the pad portion through the anisotropic conductive film, the back side of the display panel includes a first organic layer and a second organic layer, which are disposed below the adhesive layer, and an inorganic layer disposed between the first organic layer and the second organic layer. The adhesive layer has a first interface disposed between the adhesive layer and the first organic layer and a second interface disposed between the adhesive layer and the lower film, and an adhesive strength of a first portion of the first interface overlapping the bonding portion in a plan view to the first organic layer is from 100 gf/inch to 300 gf/inch, and the adhesive strength of the first portion to the first organic layer is less than an adhesive strength of the second interface to the lower film.

The display device may further includes a cover panel disposed above the lower film and below the front side of the display panel, and a third interface which is an interface between the cover panel and the lower film, a fourth interface which is an interface between the second organic layer and the anisotropic conductive film, and a fifth interface which is an interface between the anisotropic conductive film and the bonding portion, an adhesive strength of the fifth interface may be greater than an adhesive strength of the fourth interface, and the adhesive strength of the fourth interface may be greater than an adhesive strength of the third interface to the lower film.

The adhesive strength of the third interface to the lower film may be greater than the adhesive strength of the second interface to the lower film.

The adhesive strength of the first portion to the first organic layer may be within 10% difference from an adhesive strength of a second portion of the first interface to the first organic layer, which does not overlap the bonding portion in the plan view.

The adhesive strength of the first portion to the first organic layer may be different from the adhesive strength of the second portion to the first organic layer.

The adhesive strength of the first portion to the first organic layer may be smaller than the adhesive strength of the second portion to the first organic layer.

The display device may further include a moisture barrier layer disposed between the cover panel and the printed circuit board and disposed on a side of the back side of the display panel, and a functional layer disposed between the side of the back side of the display panel and the moisture barrier layer.

An electronic device according to an embodiment includes a cover window, a housing combined with the cover window, and a display device disposed in a space defined by the cover window and the housing, where the display device includes a bent display panel including a front side and a back side, which face each other, a pad portion disposed on a first surface of the back side, a printed circuit board electrically connected to the pad portion, an anisotropic conductive film disposed between the back side and the printed circuit board, an adhesive layer disposed on a second surface opposite the first surface of the back side of the display panel, and a lower film disposed on the adhesive layer, where the printed circuit board includes a bonding portion bonded to the pad portion through the anisotropic conductive film, the adhesive layer having a first interface disposed between the adhesive layer and the back side and a second interface disposed between the adhesive layer and the lower film, an adhesive strength of a first portion of the first interface overlapping the bonding portion in a plan view to the back side is from 100 gf/inch to 300 gf/inch, and the adhesive strength of the first portion to the back side is smaller than an adhesive strength of the second interface to the lower film of the second interface.

The electronic device may further include a cover panel disposed above the lower film and below the front side of the display panel, a third interface which is an interface between the cover panel and the lower film, a fourth interface which is an interface between the back side and the anisotropic conductive film, and a fifth interface which is an interface between the anisotropic conductive film and the bonding portion, where an adhesive strength of the fifth interface is greater than an adhesive strength of the fourth interface, and the adhesive strength of the fourth interface may be greater than an adhesive strength of the third interface to the lower film.

The adhesive strength of the third interface to the lower film may be greater than the adhesive strength of the second interface to the lower film.

According to embodiments, the adhesive strength of an adhesive used in a display device may be adjusted to disperse the force caused by expansion of a lower film, thereby preventing peeling between thin films of a display panel. In particular, it is possible to effectively prevent corrosion of printed circuit boards due to moisture penetration at the delamination interface by preventing peeling between the organic layer and the inorganic layer of the display panel.

### BRIEF DESCRIPTION OF THE DRAWINGS

FIG. 1 is a schematic perspective view of an electronic device according to an embodiment.

FIG. 2 is a perspective view of a display device included in an electronic device according to an embodiment.

FIG. 3 is a schematic cross-sectional view of a display device according to an embodiment.

FIG. 4 is an enlarged cross-sectional view of a portion of a display device according to an embodiment.

FIG. 5 is a table showing the adhesive strength of the interlayer interface of a display device according to an embodiment.

FIG. 6 is a plan view of an adhesive layer of a display device according to an embodiment.

FIG. 7 is an enlarged cross-sectional view of a portion of a display device according to an embodiment.

FIG. 8 is an enlarged cross-sectional view of a portion of a display device according to an embodiment.

### DETAILED DESCRIPTION

Hereinafter, various embodiments of the present disclosure will be described in detail with reference to the attached drawings so that a person having ordinary skill in the art to which the present disclosure pertains may easily implement the disclosure. The present disclosure may be embodied in many different forms and is not limited to the embodiments described herein.

In order to clearly explain the present disclosure, parts irrelevant to the description are omitted, and like reference numerals are used for like components throughout the specification.

In addition, the size and thickness of each component shown in the drawings are arbitrarily shown for convenience of explanation, so the present disclosure is not necessarily limited to that which is shown. In the drawings, the thicknesses of layers, films, panels, areas, etc., are exaggerated for clarity. And in the drawings, for convenience of explanation, the thickness of some layers and areas is exaggerated.

Also, when it is said that a part, such as a layer, membrane, area, or plate, is “over” or “on” another part, this includes not only cases where it is “directly over” the other part, but also cases where there are other parts in between. In contrast, when a part is referred to as being “directly on” another part, there are no intervening parts present. Also, being “above” or “on” a reference part means being disposed above or below the reference part, and does not necessarily mean being disposed “above” or “on” it in the opposite direction of gravity.

Additionally, throughout the specification, whenever a part is said to “include” a component, this does not mean that it excludes other components, but rather that it may include other components, unless otherwise specifically stated.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Additionally, throughout the specification, when reference is made to “in a plan view,” this means when the target portion is viewed from above (i.e., view in a thickness direction (third direction DR3) of a display device 30), and when reference is made to “in a cross-section,” it means when the target portion is viewed from the side in a cross-section cut vertically.

Throughout the specification, the term “connected” does not only mean that two or more parts are directly connected, but also that two or more parts are indirectly connected through other parts, that they are physically connected or electrically connected, as well as when parts referred to by different names depending on location or function but which are substantially one.

In the drawings, the symbols “DR1,” “DR2,” and “DR3” are used to indicate directions, wherein “DR1” is a first direction, “DR2” is a second direction perpendicular to the first direction, and “DR3” is a third direction perpendicular to the first and second directions DR1 and DR2.

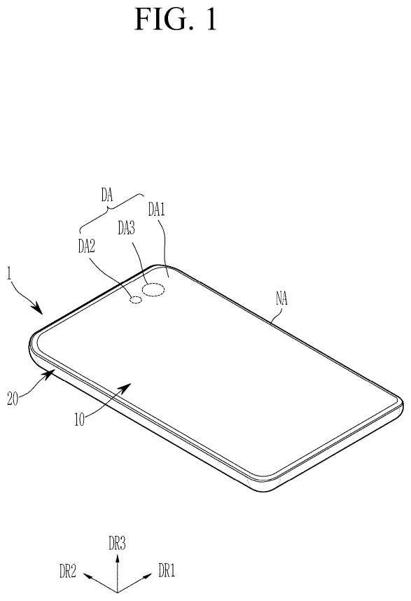

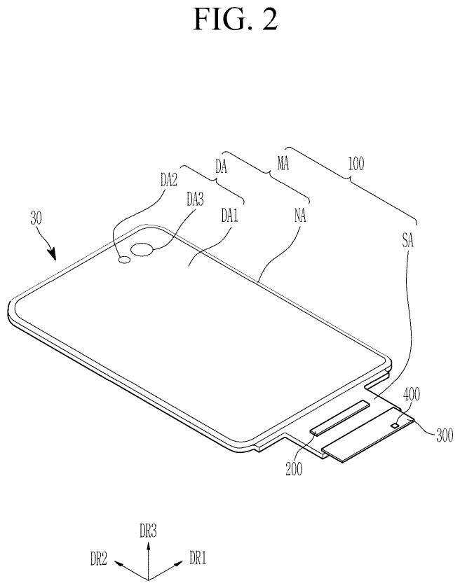

FIG. 1 is a schematic perspective view of an electronic device according to an embodiment, and FIG. 2 is a perspective view of a display device included in the electronic device according to an embodiment.

Referring to FIGS. 1 and 2, an electronic device 1 may include a display screen capable of displaying an image in the third direction DR3 corresponding to a normal direction of a plane defined by the first direction DR1 and the second direction DR2. The electronic device 1 may be a device whose main function is to display images, such as a smartphone, a mobile phone, a tablet, a multimedia player, a game console, a monitor, etc. The electronic device 1 may include a cover window 10, a housing 20, a display device 30, etc.

The cover window 10 may include an insulating panel. For example, the cover window 10 may be made of glass, plastic, or a combination thereof. The front of the cover window 10 may define the front of the electronic device 1. An area corresponding to the display screen in the cover window 10 may be optically transparent. The cover window 10 is disposed over the display device 30 to protect the display device 30 from external impacts, etc., and to transmit an image displayed by the display device 30. The cover window 10 may also be viewed as a part of the display device 30.

The housing 20 may be made of a material having relatively high rigidity. For example, the housing 20 may include a plurality of frames and/or plates made of glass, plastic, or metal, or a combination thereof. The housing 20 may be coupled with the cover window 10, and the coupled housing 20 and cover window 10 may form the exterior of the electronic device 1 and provide an internal space of the electronic device 1. For example, the housing 20 may constitute the back and side surfaces of the electronic device 1, and the cover window 10 may constitute the front side of the electronic device 1. A display device 30, etc. may be disposed in the internal space defined by the cover window 10 and the housing 20, and the display device 30, etc. may be protected from the external environment.

The display device 30 may display an image and provide the display screen of the electronic device 1. The display device 30 may be a light emitting display device such as an organic light emitting display device, an inorganic light emitting display device, or a quantum-dot light emitting display device.

The electronic device 1 may have various shapes. For example, the electronic device 1 may be a square with rounded corners when viewed from the front (i.e., in a plan view) as illustrated in FIG. 1. In addition, the electronic device 1 may have a shape such as a rectangle, a square, another polygon, a circle, an oval, etc.

The electronic device 1 and the display device 30 may each include a display area DA and a non-display area NA. The display area DA and the non-display area NA illustrated in FIG. 1 may correspond to the display area DA and the non-display area NA of the display device 30 illustrated in FIG. 2. The display area DA is the area where the image is displayed and may correspond to the display screen. The non-display area NA is the area where the image is not displayed. The display area DA may occupy most of the area from the front to the center of the electronic device 1, and the non-display area NA may surround the display area DA.

The display area DA may include a first display area DA1, a second display area DA2, and a third display area DA3. The second display area DA2 and the third display area DA3 may be areas where parts such as sensors and cameras for adding various functions to the electronic device 1 are placed on the back. The second display area DA2 and the third display area DA3 may correspond to component areas. The second display area DA2 and the third display area DA3 may be surrounded by the first display area DA1. Not only the first display area DA1, but also the second display area DA2 and the third display area DA3 may all display images. The positions and numbers of the second display area DA2 and the third display area DA3 may be varied.

To describe the display device 30 in more detail, the display device 30 may provide a display screen in the electronic device 1. The display device 30 may detect or capture the front of the electronic device 1. The display device 30 may have a flat shape similar to the electronic device 1.

The display device 30 may include a display panel 100, a display driver 200, a flexible printed circuit board 300, a touch driver 400, etc.

The display panel 100 may be attached to the cover window 10 by an adhesive layer. The display panel 100 may include a main area MA and a sub-area SA.

The main area MA may include a display area DA in which pixels displaying an image are arranged, and a non-display area NA surrounding the display area DA. The display area DA may include a first display area DA1, a second display area DA2, and a third display area DA3. Components such as sensors or cameras may be placed on the back of the second display area DA2 and the third display area DA3, and the second display area DA2 and the third display area DA3 may correspond to component areas.

The display area DA may emit light in a third direction DR3 from light emitting areas corresponding to the light emitting elements. For example, the display panel 100 may include a pixel circuit unit including transistors, signal lines (e.g., gate lines, data lines, voltage lines) connected to the pixel circuit unit, and a light emitting element connected to the pixel circuit unit. The display panel 100 may include a pixel defining layer having an opening that defines a light emitting area of each light emitting element. The light emitting element may include an organic light emitting diode including an organic light emitting layer, a quantum-dot light emitting diode including a quantum-dot light emitting layer, an inorganic light emitting diode including an inorganic semiconductor, and/or a micro-light emitting diode.

The non-display area NA may surround the display area DA. The non-display area NA may be defined as an edge area of the main area MA of the display panel 100. Circuits and/or signal lines for generating and/or transmitting various signals applied to the display area DA may be arranged in the non-display area NA. For example, a gate driver (not shown) that supplies gate signals to gate lines and fan-out lines (not shown) that connect the signal lines of the display driver 200 and the display area DA may be disposed in the non-display area NA.

The sub-area SA may be an area extending from one side of a main area MA. The sub-area SA may include a flexible area capable of bending, folding, rolling, etc. For example, the sub-area SA may be bent to overlap the main area MA in the thickness direction (third direction DR3). The display driver 200 may be disposed in the sub-area SA, and a pad unit may be disposed at the edge of the sub-area SA. The printed circuit board 300 may be connected to the pad portion. In another embodiment, the sub-area SA may be omitted, and the display driver 200 and pad area may be placed in the non-display area NA.

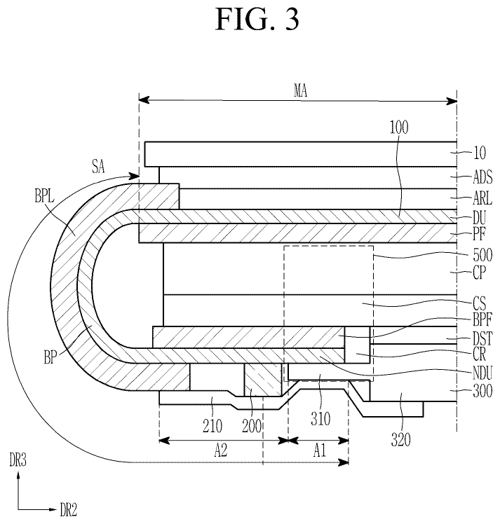

FIG. 3 is a schematic cross-sectional view of a display device according to an embodiment. Below, with reference to FIG. 3, a schematic cross-section of a bent display panel in a display device is examined.

The display panel 100 may include the main area MA and the sub-area SA. The main area MA may include a front side DU (also referred to as a display portion), and the sub-area SA may include a back side NDU (also referred to as a non-display portion) that may be folded and disposed on the back side of the front side DU, and a bending portion BP disposed between the back side NDU and the front side DU.

The cover window 10 may be disposed over the display panel 100. The cover window 10 may protect the front side DU of the display panel 100. The cover window 10 may be attached to the display panel 100 by an adhesive material ADS such as an optically clear adhesive OCA.

At least one optical layer ARL may be disposed between the display panel 100 and the cover window 10. At least one optical layer ARL may reduce the amount of light incident from the outside onto the display panel 100 and be reflected by the display panel 100. At least one optical layer ARL may include a polarizing layer. In some embodiments, the optical layer ARL may include a combination of a color filter and a light blocking member instead of a polarizing layer.

The front side DU may include a substrate and a driving element layer, a light emitting element layer, and an encapsulation layer disposed on the substrate.

The substrate may be a base substrate or a base member. The substrate may be a flexible substrate including a polymer resin such as polyimide, polyamide, or polyethylene terephthalate. According to an embodiment, the substrate may be a rigid substrate made of a material such as glass. The driving element layer may be disposed on the surface of the substrate. The driving element layer may include transistors and capacitors that constitute pixel circuits that output driving currents to the light emitting elements.

The driving element layer may include gate lines, data lines, power lines, gate control lines, fan-out lines connecting the display driver 200 and the data lines, and lead lines connecting the display driver 200 and pads on the substrate. The driving element layer may include transistors and capacitors constituting the gate driving unit, and gate control lines. The driving element layer may include conductive layers, semiconductor layers, and insulating layers, and a combination of these may form transistors, capacitors, and signal lines and serve as insulation between electrical elements.

The light emitting element layer may be disposed over the driving element layer and may include light emitting elements and corresponding light emitting areas. The light emitting element layer may include a pixel defining layer having openings defining light emitting areas.

An encapsulation layer (or thin-film encapsulation layer) may be further disposed on top of the light emitting element layer. The encapsulating layer may cover the upper surface and side surfaces of the light emitting element layer, and may prevent moisture or oxygen from penetrating into the light emitting element layer from the outside. The encapsulating layer may include one or more inorganic layers and one or more organic layers.

A bend protection layer BPL (or stress neutralization layer) may be disposed above the bend portion BP to relieve stress on the wiring disposed at the bend portion BP.

The back side NDU may be attached and affixed to the back side of the front side DU by a spacer CS or double-sided tape containing an adhesive material on both sides. On the lower surface of the back side NDU in the bent state (referred to as the first surface), a pad portion including a plurality of pads is disposed, and a printed circuit board 300 may be electrically connected to the pad portion.

A printed circuit board 300 may include a body portion (indicated by 320) and a bonding portion 310 extending from the body portion. The bonding portion 310 may include a plurality of pads. The bonding portion 310 may be electrically connected to the display panel 100 by being bonded to the pad portion of the back side NDU of the display panel 100. The printed circuit board 300 may be disposed on the back side of the front side DU in the bent state of the display panel 100. The body portion 320 of the printed circuit board 300 may be attached and affixed to the back side of the front portion DU using a double-sided tape DST or a spacer including an adhesive layer on both sides.

When the bending portion BP of the display panel 100 is bent, a protective film PF may be disposed on the lower surface of the front side DU, and a bottom protective film BPF may be disposed on the upper surface of the back side NDU (i.e., the second surface opposite the first surface of the back side NDU).

A protective film PF may protect the display panel 100 during the manufacturing process of the display device 30, etc. The protective film PF may not be disposed at the bending portion BP of the sub-area SA.

The protective film PF may include at least one of polymer resins such as polyethylene terephthalate (“PET”), poly(butylene terephthalate) (“PBT”), polycarbonate (“PC”), polyethylene naphthalate (“PEN”), polystyrene, polymethyl methacrylate (“PMMA”), polyvinylchloride (“PVC”), polyether sulfone (“PES”), polypropylene (“PP”), and polyamide (“PA”), and a cover panel CP may be disposed under the protective film PF. The cover panel CP may have a multilayer structure. The cover panel CP may include a metal layer including a metal with excellent thermal conductivity and shielding performance, such as copper or aluminum, a reinforcing layer to secure the strength of upper layers, and a cushion layer that may absorb impact and prevent the display panel 100 from being damaged.

A spacer CS may be disposed under the cover panel CP. The spacer CS may maintain and secure the gap between the front portion DU and the back side NDU when the display panel 100 is bent. Depending on the embodiment, the spacer CS may be composed of a single layer or multiple layers, such as a cushion layer and a polymer layer.

The bottom protective film BPF may be disposed under the spacer CS. The bottom protective film BPF may be disposed on the second surface of the back side NDU of the display panel 100 to protect the display panel 100. The bottom protective film BPF may be the same material as the protective film PF, and may include at least one of polymer resins such as polyethylene terephthalate (PET), poly(butylene terephthalate) (PBT), polycarbonate (PC), polyethylene naphthalate (PEN), polystyrene, polymethyl methacrylate (PMMA), polyvinylchloride (PVC), polyether sulfone (PES), polypropylene (PP), and polyamide (PA). The thickness of the bottom protective film BPF in the third direction DR3 may be 70 micrometers (μm) to 80 μm.

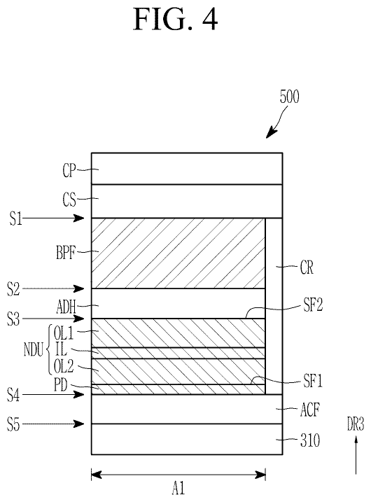

The back side NDU may be disposed under the bottom protective film BPF. The back side NDU may include a first surface SF1 electrically connected to the bonding portion 310 of the printed circuit board 300 and a second surface SF2 attached through the bottom protective film BPF through an adhesive layer (ADH of FIG. 4).

The display driver 200 may be disposed on the first surface SF1 of the back side NDU of the display panel 100. The display driver 200 may output signals and voltages for driving the display panel 100. The display driver 200 may supply data voltages to the data lines. The display driver 200 may supply power voltage to power lines, and the display driver 200 may be in the form of an integrated circuit chip and may be mounted on the display panel 100. For example, the display driver 200 may be placed on the back side NDU of the sub-area SA and may overlap with the main area MA—i.e., the front side DU—in the thickness direction (third direction DR3). In another embodiment, the display driver 200 may be mounted on a printed circuit board 300.

A printed circuit board 300 may include a body portion (indicated by 300) and a bonding portion 310 extending from the body portion. The body portion may occupy the largest area in the flexible printed circuit board 300 and may have a multilayer structure. For example, the body portion may include four or more conductive layers. Components such as a touch actuator, a capacitor, a resistor, and an inductor may be disposed in the body.

The bonding portion 310 may be disposed along the edge of the body. The bonding portion 310 may extend in the first direction DR1. The bonding portion 310 may be joined to the pad portion of the display panel 100 using an electrical and physical joining means such as an anisotropic conductive film. The bonding portion 310 may include a plurality of pads for electrical connection with the display panel 100. The pads disposed in the bonding portion 310 of the printed circuit board 300 may be electrically connected to the pads disposed in the pad portion of the display panel 100. The bonding portion 310 may include one or more conductive layers. The number of conductive layers included in the bonding portion 310 may be less than the number of conductive layers included in the body portion. For example, the bonding portion 310 may include one or two conductive layers, and the body portion may include four or more conductive layers.

The printed circuit board 300 may be disposed on the back side of the front side DU in the bent state of the display panel 100. The body portion of the printed circuit board 300 may be attached and affixed to the back side of the front side DU using a double-sided tape DST or a spacer including an adhesive layer on both sides.

Referring to FIG. 2, the touch driver 400 may be in the form of an integrated circuit chip and may be mounted on the printed circuit board 300. The touch driver 400 may be electrically connected to a touch sensing portion included in the electronic device 1. The touch sensing portion may be provided in the display area DA of the display panel 100. The touch driver 400 may supply an input signal (touch driving signal) to the sensing electrodes of the touch sensing portion, and may detect a change in electrostatic capacity between the sensing electrodes based on an output signal (touch sensing signal) from the sensing electrodes. For example, the touch actuation signal may be a pulse signal having a predetermined frequency. The touch driver may calculate whether a touch has occurred and the touch coordinates based on the amount of change in electrostatic capacity between the detection electrodes. The touch driver 400 may be provided as an integrated circuit chip.

Referring to FIG. 3, the display driver 200 and at least a portion of the sub-area SA and the printed circuit board 300 may be covered by a cover 210. The cover 210 is disposed below the body portion 320, the bonding portion 310 and the display driver 200 of the printed circuit board 300, and may be attached to the display driver 200 and the sub-area SA and the printed circuit board 300. The cover 210 is applied to cover at least a portion of the display driver 200 and the printed circuit board 300 to protect them from electromagnetic interference EMI and electrostatic discharge ESD. In addition, the cover 210 may prevent the display driver 200, the bonding portion 310, etc. from direct contact with external objects, thereby protecting them from physical damage due to friction, etc. The cover 210 may be made of a flexible material capable of shielding EMI, ESD, etc. For example, the cover 210 may be in the form of a tape including a metal layer. The metal layer of the cover 210 may include a metal foil, a metal fabric, a metal mesh, etc. An adhesive layer may be disposed on one side of the cover 210.

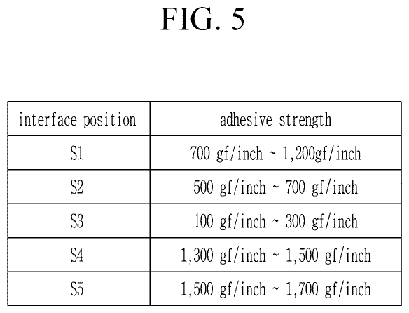

FIG. 4 is an enlarged cross-sectional view of a portion of a display device according to an embodiment, illustrating the structure 500 in FIG. 3 on an enlarged scale. FIG. 5 is a table showing the adhesive strength of the interlayer interface of the display device. Below, the structure 500 and the adhesive strength of each layer of the structure 500 will be examined with reference to FIGS. 4 and 5.

The structure 500, which is the lower structure of the front part DU of the display device, shows, from bottom to top, the stacked structure of the bonding portion 310 of the printed circuit board, the back side NDU, the bottom protective film BPF, the spacer CS, and the cover panel CP.

According to FIG. 4, the bottom protective film BPF and the back side NDU are attached to each other by an adhesive layer ADH. The adhesive layer ADH may include a pressure-sensitive adhesive PSA or an optically clear adhesive OCA. More specifically, the adhesive layer ADH may include a polymer resin such as, for example, an acrylic material, a silicone material, rubber, polyurethane, vinyl acetate, epoxy resin, or styrene-butadiene-styrene (SBS). The adhesive layer ADH has a first interface S3 disposed with the back side NDU of the display panel 100 and a second interface S2 disposed with the bottom protective film BPF.

The back side NDU of the display panel 100 may be formed of multiple layers. The back side NDU may include a first organic layer OL1 disposed adjacent to the adhesive layer ADH, an inorganic layer IL disposed beneath the first organic layer OL1, and a second organic layer OL2 disposed beneath the inorganic layer IL. The first organic layer OL1, the inorganic layer IL, and the second organic layer OL2 may together form a substrate.

A pad portion PD is disposed below the second organic layer OL2, and the pad portion PD may be electrically connected to a bonding portion 310 of a printed circuit board through an anisotropic conductive film ACF. The pad portion PD may be disposed on the first surface SF1 of the back side NDU.

The thickness of the adhesive layer ADH may be 10 μm to 20 μm. Unless otherwise stated in the description below, the thickness refers to the thickness in the third direction DR3. The thickness of the first organic layer OL1 may be 7 μm to 13 μm. The thickness of the inorganic layer IL may be 0.3 μm to 0.9 μm. The thickness of the second organic layer OL2 may be 4 μm to 6 μm. The thickness of the anisotropic conductive film ACF may be 20 μm to 24 μm.

The pad portion PD may include multiple pads. The pads may be formed of a metal material, which is the same material as one of the plurality of electrodes formed on the front side DU, and may be formed simultaneously with the plurality of electrodes. For example, the pad portion may include a metal or metal alloy such as copper (Cu), aluminum (Al), silver (Ag), molybdenum (Mo), chromium (Cr), gold (Au), platinum (Pt), palladium (Pd), tantalum (Ta), tungsten (W), titanium (Ti), or nickel (Ni). The pads of the pad portion PD may be connected to a wiring portion that is bent along the bend portion of the display panel.

The display device according to the embodiment may further include a moisture barrier layer CR. The moisture barrier layer CR is disposed between the cover panel CP and the printed circuit board, and may be disposed on the side of the back side NDU. The moisture barrier layer CR is intended to prevent moisture from penetrating from the outside and may include a polymeric thin film.

However, it is not limited to this and may include any one of an oxide thin film, a metal thin film, a polymer thin film, or an organic-inorganic composite layer.

Referring to FIG. 4, a display device according to an embodiment may further include the first interface S3, the second interface S2, the third interface S1, the fourth interface S4, and the fifth interface S5 described above. As described above, the adhesive layer ADH may have a first interface S3 disposed with the display panel 100 and a second interface S2 disposed with the bottom protective film BPF. The third interface S1 may be an interface between the cover panel CP and the bottom protective film BPF. The fourth interface S4 may be an interface between the pad portion PD and the anisotropic conductive film ACF, and the fifth interface S5 may be an interface between the anisotropic conductive film ACF and the bonding portion 310.

Referring to FIGS. 4 and 5, the adhesive strength of a first portion A1 of the first interface S3 overlapping the bonding portion 310 in a plan view to the display panel 100 may be from 100 gf/inch to 300 gf/inch. The adhesive strength, to the display panel 100, of the first portion A1 of the first interface S3 overlapping the bonding portion 310 in a plan view may be 100 gf/inch to 300 gf/inch. The adhesive strength, to the display panel 100, of the first portion A1 may be the same as the adhesive strength, to the display panel, of a second portion A2 of the first interface S3 which is disposed apart from or does not overlap the bonding portion 310 of the first interface S3 in a plan view within a margin of error of 10%. In other words, the adhesive strength of the first portion A1 may be within 10% difference from the adhesive strength of the second portion A2. In this description, the term “plane” means a plain structure defined by the first direction DR1 and the second direction DR2. The adhesive strength, to the display panel 100, of the first portion A1 may be less than the adhesive strength of the second interface S2 to the bottom protective film BPF.

The adhesive strength, to the first organic layer OL1, of the first portion A1 of the first interface S3, which overlaps the bonding portion 310 in a plan view may be 100 gf/inch to 300 gf/inch. The adhesive strength, to the first organic layer OL1, of the second portion A2 of the first interface S3, which is spaced apart from the bonding portion 310 in a plan view may be within a 10% difference from the adhesive strength, to the first organic layer OL1, of the first portion A1 of the first interface S3, which overlaps the bonding portion 310 in a plan view. The adhesive strength, to the first organic layer OL1, of the first portion A1 may be smaller than the adhesive strength of the second interface S2 to the bottom protective film BPF.

In order to prevent moisture penetration into the display device when operating in a high-temperature and high-humidity environment, strong adhesion to the display panel 100 of the first interface S3 of the adhesive layer ADH may be required. However, if the adhesive strength, to the display panel 100, of the first interface S3 of the adhesive layer ADH is too strong, peeling may occur between the second organic layer OL2 and the inorganic layer IL within the display panel 100 due to a force applied in the vertical direction (e.g., the third direction DR3) of the bottom protective film BPF due to expansion and contraction of the bottom protective film BPF and a shear force applied in the left-right direction (e.g., the first direction DR1 or the second direction DR2) of the display device, or peeling may also occur between the display panel 100 and the anisotropic conductive film ACF. In addition, peeling between the second organic layer OL2 and the inorganic layer IL and peeling between the display panel 100 and the anisotropic conductive film ACF may occur simultaneously. When delamination occurs in this way, moisture may penetrate along the delamination interface. When moisture penetration occurs along the delamination interface, electrolytes and ions caused by moisture may be introduced. Electrolytes and ions generate a potential difference between adjacent pads in the pad portion, and an electrochemical reaction occurs due to the ion component, which may cause corrosion of the printed circuit board 300 and the pad portion PD. Corrosion of the printed circuit board 300 and the pad portion PD may cause a malfunction in the operation of the display device.

Accordingly, in order to prevent peeling from occurring at the interface around the printed circuit board 300 and the pad portion PD, the adhesive strength of the first interface S3 of the adhesive layer ADH to the display panel 100 (the back side NDU) may be lowered compared to the adhesive strength of the second interface S2 by minimizing the force applied by the bottom protective film BPF in the up-down direction (third direction DR3) of the bottom protective film BPF and the shear force applied in the left-right direction (i.e., direction perpendicular to the third direction DR3) of the display panel 100 of the display device. Only the adhesive strength, to the display panel 100, of the first interface S3 may be adjusted downward to be designed to be smaller than the adhesive strength, to the bottom protective film BPF, of the second interface S2. When the adhesive strength of the first interface S3 to the display panel 100 is reduced, peeling may occur between the first interface S3 and the display panel 100 due to the force applied by the contraction and expansion of the bottom protective film BPF. When such peeling occurs, the force applied to the display panel 100 is dispersed due to the shrinkage and expansion of the bottom protective film BPF, so that the magnitude of the force transmitted to the display panel 100 and the anisotropic conductive film ACF is reduced, thereby preventing peeling that may occur between the organic layers OL1, OL2 and the inorganic layer IL of the display panel 100 and peeling between the back side NDU and the anisotropic conductive film ACF.

Referring to FIG. 5, the adhesive strength of the fifth interface S5 of the anisotropic conductive film ACF to the bonding portion 310 may be 1,500 gf/inch to 1,700 gf/inch. Strong adhesive strength may be required to prevent current conduction and moisture penetration between pads existing between the bonding portion 310 and the anisotropic conductive film ACF. The adhesive strength of the fifth interface S5 of the anisotropic conductive film ACF to the bonding portion 310 may be greater than the adhesive strength of the fourth interface S4 of the pad portion PD to the anisotropic conductive film ACF.

The adhesive strength of the fourth interface S4 between the anisotropic conductive film ACF and the back side NDU of the display panel may be from 1,300 gf/inch to 1,500 gf/inch. The fourth interface S4 of the anisotropic conductive film ACF between the anisotropic conductive film ACF and the back side NDU of the display panel 100 may require strong adhesive strength to prevent electrification and moisture penetration. The adhesive strength of the fourth interface S4 of the anisotropic conductive film ACF to the back side NDU may be greater than the adhesive strength of the third interface S1 of the adhesive layer between the spacer CS and the bottom protective film BPF to the bottom protective film BPF.

The adhesive strength of the third interface S1 of the adhesive layer between the spacer CS and the bottom protective film BPF to the bottom protective film BPF may be from 700 gf/inch to 1,200 gf/inch. When the adhesive strength, to the bottom protective film BPF, of the third interface S1 of the adhesive layer between the spacer CS and the bottom protective film BPF is adjusted downward, it may help to minimize the vertical force and shear force applied to the display device. The adhesive strength, to the bottom protective film BPF, of the third interface S1 of the adhesive layer between the spacer CS and the bottom protective film BPF may be greater than the adhesive strength, to the bottom protective film BPF, of the second interface S2 of the adhesive layer ADH.

The adhesive strength, to the back side NDU, of the first interface S3 of the adhesive layer ADH of the display panel 100 may be from 100 gf/inch to 300 gf/inch, and the adhesive strength, to the bottom protective film BPF, of the second interface S2 of the adhesive layer ADH may be 500 gf/inch to 700 gf/inch. In order to reduce the force applied to the display device due to expansion and contraction of the bottom protective film BPF during operation, the adhesive strength of the first interface S3 closer to the display driver 200 to the display panel 100 may be adjusted downward.

Therefore, when selecting a material for the adhesive layer ADH, a material with relatively low adhesive strength may be selected. However, since the adhesive strength, to the bottom protective film BPF, of the second interface S2 of the adhesive layer ADH is designed to be greater than the adhesive strength, to the display panel 100, of the first interface S3 of the adhesive layer ADH, surface treatment may be required for the second interface S2 of the adhesive layer ADH or the bottom protective film BPF. A chemical treatment may be performed to increase the van der Waals force between the first interface S3 of the adhesive layer ADH and the display panel 100, and a physical treatment may be performed to roughen the surface of the display panel 100 to increase the adhesive strength.

Referring to FIG. 3 together with FIG. 5, the cover 210 may be disposed below the body portion 320 and the bonding portion 310 of the printed circuit board 300. According to an embodiment, the display device may adjust the adhesive strength, to the body portion 320, of the cover 210 downward from 500 gf/inch to 1,200 gf/inch. Therefore, depending on the high-temperature and high-humidity environment, the overlapping portion of the cover 210 and the body portion 320 may be subject to lifting. Likewise, the force applied to the display panel due to the contraction and expansion of the bottom protective film BPF may be distributed through the lifting between the cover 210 and the body portion 320. However, since the cover 210 is intended to protect the display driver 200, lifting and delamination may not occur between the display driver 200 and the cover 210.

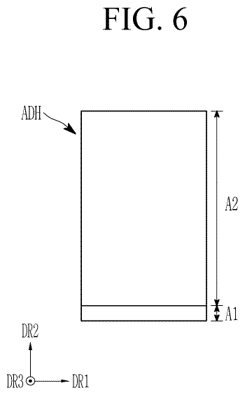

FIG. 6 is a plan view showing the adhesive strength of an adhesive layer of a display device according to an embodiment. The adhesive layers ADH with different adhesive strengths in the first portion A1 and the second portion A2 will be examined below. As described above, the portion of the first interface S3 of the adhesive layer ADH that overlaps with the bonding portion 310 in a plan view may be the first portion A1, and the remaining portion may be the second portion A2. That is, the second portion A2 may be spaced apart from the planar bonding portion 310 without overlapping it.

In an embodiment, the display device may have an adhesive strength, to a display panel 100, of a first portion A1 of an adhesive layer ADH that may be different from an adhesive strength, to the display panel 100, of a second portion A2 of the first interface S3, which is disposed apart from the bonding portion 310 in a plan view. The adhesive strength, to the display panel 100, of the first portion A1 may be less than the adhesive strength of the second portion A2 to the display panel 100. The adhesive strength between the first portion A1 and the display panel 100 may be from 100 gf/inch to 300 gf/inch. The adhesive strength between the first portion A1 and the first organic layer OL1 illustrated in FIG. 4 may be from 100 gf/inch to 300 gf/inch. The adhesive strength to the second portion A2 and the display panel 100 may be from 500 gf/inch to 700 gf/inch. An adhesive material having lower adhesive strength than an adhesive strength of the second portion A2 may be used in the first portion A1, and an adhesive material having higher adhesive strength than the adhesive strength of the first portion A1 may be used in the second portion A2.

By using an adhesive material having a relatively low adhesive strength in the first portion A1, the gap between the first portion A1 and the display panel 100 may be raised more than the second portion A2 in a display device operated in an environment such as high temperature and high humidity. Even if only the first portion A1, which is a part of the first interface S3, is delaminated with the display panel 100, the force applied to the display device may be distributed through the lifting between the first portion A1 and the display panel 100 as the bottom protective film BPF contracts and expands when the display device is operated.

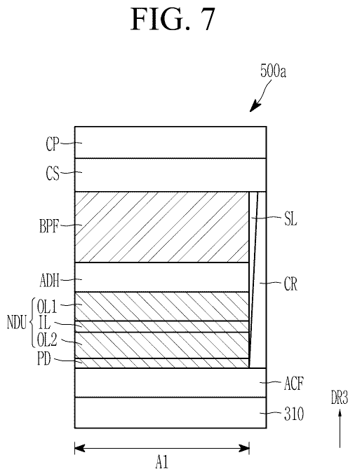

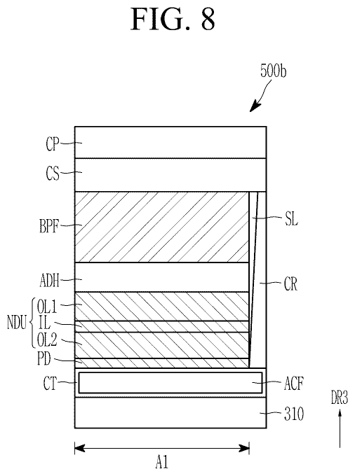

FIGS. 7 and 8 are enlarged cross-sectional views of a portion of a display device according to an embodiment. FIG. 7 illustrates a structure 500a further including a functional layer SL disposed between the display panel 100 and the moisture barrier layer CR according to an embodiment. FIG. 8 shows a structure 500b for preventing additional moisture penetration by applying a hydrophobic treatment to the anisotropic conductive film ACF in the display device according to an embodiment.

According to FIG. 7, a display device according to an embodiment may further include the functional layer SL disposed between the display panel 100 and the moisture barrier layer CR. When positioning the moisture barrier layer CR on the side of the back side NDU of the display panel 100 and between the cover panel CP and the printed circuit board 300, the moisture barrier layer CR may not be in close contact with the side of the display panel 100 and a gap may exist therebetween. These gaps may be filled with the functional layer SL.

The narrow gap between the back side NDU of the display panel 100 and the moisture barrier layer CR may be filled with the functional layer SL using capillary action. The functional layer SL may contain inorganic substances. The functional layer SL may include at least one of silicon nitride SiNx or silicon oxide SiOx. However, without limitation, the functional layer SL may include any one of an oxide thin film, a metal thin film, a polymer thin film, or an organic-inorganic composite layer that is effective in preventing moisture permeation.

According to FIG. 8, the structure 500b of the display device according to an embodiment may further include a coating layer CT surrounding the anisotropic conductive film ACF. The coating layer CT may further prevent moisture penetration into the display device by including a hydrophobic ligand. The hydrophobic ligand may be at least one of, but is not limited to, hexanethiol, octanethiol, dodecanethiol, and lauric acid.

According to the display device according to an embodiment, by reducing the adhesive strength force between the first interface S3 of the adhesive layer ADH and the back side NDU or the first organic layer OL1 of the display panel 100, the force exerted on the display panel 100 due to the expansion of the bottom protective film BPF when the display device is in operation may be dispersed by lifting the first interface S3 and the back side NDU or the first organic layer OL1 of the display panel 100. It is possible to prevent delamination between the organic layers OL1, OL2 and the inorganic layer IL of the display panel 100, as well as delamination between the rear surface NDU and the anisotropic conductive film ACF, and it is possible to prevent moisture from entering the delaminated interface, thereby suppressing poor operation due to corrosion of the anisotropic conductive film ACF and the printed circuit board 300.

Although the embodiments of the present disclosure have been described in detail above, the scope of the present disclosure is not limited thereto, and various modifications and improvements made by those skilled in the art using the basic concepts of the present disclosure defined in the following claims also fall within the scope of the present disclosure.

### DESCRIPTION OF SYMBOLS

1: electronic device
10: cover window
20: housing
30: display device
100: display panel
200: display driver
210: cover
300: printed circuit board
310: bonding portion
400: touch driver
500, 500a, 500b: structure
ADS: adhesive material
ADH: adhesive layer
ARL: optical layer
BPF: lower film
CP: cover panel
DU: front side
CR: moisture barrier layer
CS: spacer
IL: inorganic layer
NDU: back side
OL1: first organic layer
OL2: second organic layer
PD: pad portion
PF: protective film
SL: functional layer

What is claimed is:

1. A display device, comprising:
a bent display panel comprising a front side and a back side, which face each other;
a pad portion disposed on a first surface of the back side;
a printed circuit board electrically connected to the pad portion;
an anisotropic conductive film disposed between the back side and the printed circuit board;
an adhesive layer disposed on a second surface opposite to the first surface of the back side of the display panel; and
a lower film disposed on the adhesive layer,
wherein the printed circuit board comprises a bonding portion bonded to the pad portion through the anisotropic conductive film,
the adhesive layer has a first interface disposed between the adhesive layer and the back side and a second interface disposed between the adhesive layer and the lower film,
an adhesive strength of a first portion of the first interface overlapping the bonding portion in a plan view to the back side is from 100 gram-force per inch (gf/inch) to 300 gf/inch, and
the adhesive strength of the first portion to the back side is smaller than an adhesive strength of the second interface to the lower film.

2. The display device of claim 1, further comprising:
a cover panel disposed above the lower film and below the front side of the display panel;
a third interface, which is an interface between the cover panel and the lower film;
a fourth interface, which is an interface between the back side and the anisotropic conductive film, and
a fifth interface, which is an interface between the anisotropic conductive film and the bonding portion,
wherein an adhesive strength of the fifth interface to the bonding portion is greater than an adhesive strength of the fourth interface to the anisotropic conductive film, and the adhesive strength of the fourth interface is greater than an adhesive strength of the third interface to the lower film.

3. The display device of claim 2, wherein:
the adhesive strength of the third interface to the lower film is greater than the adhesive strength of the second interface to the lower film.

4. The display device of claim 3, wherein:
the adhesive strength of the third interface to the lower film is from 700 gf/inch to 1,200 gf/inch.

5. The display device of claim 3, wherein:
the adhesive strength of the second interface to the adhesive layer is from 500 gf/inch to 700 gf/inch.

6. The display device of claim 3, wherein:
the adhesive strength of the fourth interface to the anisotropic conductive film is from 1,300 gf/inch to 1,500 gf/inch.

7. The display device of claim 3, wherein:
the adhesive strength of the fifth interface to the bonding portion is from 1,500 gf/inch to 1,700 gf/inch.

8. The display device of claim 3, wherein:
the adhesive strength of the first portion to the back side is within 10% difference from an adhesive strength of a second portion of the first interface to the back side, which does not overlap the bonding portion in the plan view.

9. The display device of claim 3, wherein:
the adhesive strength of the first portion to the back side is different from an adhesive strength of a second portion of the first interface to the back side, which does not overlap the bonding portion in the plan view.

10. The display device of claim 9, wherein:
the adhesive strength of the first portion to the back side is smaller than the adhesive strength of the second portion to the back side.

11. The display device of claim 3, further comprising:
a moisture barrier layer disposed between the cover panel and the printed circuit board and disposed on a side of the back side, and
a functional layer disposed between the side of the back side and the moisture barrier layer.

12. The display device of claim 3, further comprising:
a coating layer surrounding the anisotropic conductive film, wherein the coating layer includes a hydrophobic ligand.

13. The display device of claim 3,
wherein the printed circuit board further includes a body portion on which components are arranged, and
wherein a cover is disposed below the body portion, the bonding portion, and a display driving part,
wherein an adhesive strength of the cover to the body portion is from 500 gf/inch to 1,200 gf/inch.

14. A display device, comprising:
a bent display panel including a front side and a back side, which face each other;
a pad portion disposed on a first surface of the back side;
a printed circuit board electrically connected to the pad portion;
an anisotropic conductive film disposed between the back side and the printed circuit board;
an adhesive layer disposed on a second surface opposite to the first surface of the back side of the display panel; and
a lower film disposed on the adhesive layer,
wherein the printed circuit board comprises a bonding portion bonded to the pad portion through the anisotropic conductive film,
the back side of the display panel comprises
a first organic layer and a second organic layer, which are disposed below the adhesive layer; and
an inorganic layer disposed between the first organic layer and the second organic layer,
wherein the adhesive layer has a first interface disposed between the adhesive layer and the first organic layer and a second interface disposed between the adhesive layer and the lower film,
an adhesive strength of a first portion of the first interface overlapping the bonding portion in a plan view to the first organic layer is from 100 gf/inch to 300 gf/inch, and
the adhesive strength of the first portion to the first organic layer is smaller than an adhesive strength of the second interface to the lower film.

15. The display device of claim 14, further comprising:
a cover panel disposed above the lower film and below the front side of the display panel;
a third interface, which is an interface between the cover panel and the lower film;
a fourth interface, which is an interface between the second organic layer and the anisotropic conductive film, and
a fifth interface, which is an interface between the anisotropic conductive film and the bonding portion,
an adhesive strength of the fifth interface is greater than an adhesive strength of the fourth interface,
wherein the adhesive strength of the fourth interface is greater than an adhesive strength of the third interface to the lower film.

16. The display device of claim 15, wherein:
the adhesive strength of the third interface to the lower film is greater than the adhesive strength of the second interface to the lower film.

17. The display device of claim 16, wherein:
the adhesive strength of the first portion to the first organic layer is within 10% difference from an adhesive strength of a second portion of the first interface to the first organic layer, which does not overlap the bonding portion in the plan view.

18. The display device of claim 16, wherein:
the adhesive strength of the first portion to the first organic layer is different from an adhesive strength of a second portion of the first interface to the first organic layer, which does not overlap the bonding portion in the plan view.

19. The display device of claim 18, wherein:
the adhesive strength of the first portion to the first organic layer is smaller than the adhesive strength of the second portion to the first organic layer.

20. An electronic device, comprising:
a cover window;
a housing combined with the cover window; and
a display device disposed in a space defined by the cover window and the housing,
wherein the display device comprises,
a bent display panel comprising a front side and a back side, which face each other;
a pad portion disposed on a first surface of the back side;
a printed circuit board electrically connected to the pad portion;
an anisotropic conductive film disposed between the back side and the printed circuit board;
an adhesive layer disposed on a second surface opposite to the first surface of the back side of the display panel; and
a lower film disposed on the adhesive layer,
wherein the printed circuit board comprises a bonding portion bonded to the pad portion through the anisotropic conductive film,
the adhesive layer has a first interface disposed between the adhesive layer and the back side and a second interface disposed between the adhesive layer and the lower film,
an adhesive strength of a first portion of the first interface overlapping the bonding portion in a plan view to the back side is from 100 gf/inch to 300 gf/inch, and
the adhesive strength of the first portion to the back side is smaller than an adhesive strength of the second interface to the lower film.
